(19) United States
(12) Patent Application Publication
(10) Pub. No.: US 2015/0371905 A1
(43) Pub. Date: Dec. 24, 2015

(54) SOI WITH GOLD-DOPED HANDLE WAFER

(71) Applicant: RF Micro Devices, Inc., Greensboro, NC (US)

(72) Inventors: Michael Carroll, Jamestown, NC (US); Julio C. Costa, Oak Ridge, NC (US); Philip W. Mason, Greensboro, NC (US); Edward T. Spears, Oak Ridge, NC (US); Bill Rhyne, Summerfield, NC (US)

(21) Appl. No.: 14/746,005

(22) Filed: Jun. 22, 2015

Related U.S. Application Data
(60) Provisional application No. 62/014,876, filed on Jun. 20, 2014.

(51) Int. Cl. H01L 21/84; H01L 21/304; H01L 21/683; H01L 29/10; H01L 27/12; H01L 23/00; H01L 29/167; H01L 21/78; H01L 27/092

(52) U.S. Cl. CPC H01L 21/84; H01L 21/78; H01L 21/304; H01L 21/6835; H01L 27/092; H01L 27/1203; H01L 24/13; H01L 29/167; H01L 29/1079; H01L 2221/68327; H01L 2221/68381

(57) ABSTRACT

A method for manufacturing a semiconductor die includes providing an SOI semiconductor wafer including a substrate, an insulating layer over the substrate, and a device layer over the insulating layer. A surface of the SOI semiconductor wafer opposite the substrate is mounted to a temporary carrier mount, and the substrate is removed, leaving an exposed surface of the insulating layer. A high-resistivity gold-doped silicon substrate is then provided on the exposed surface of the insulating layer. By providing the high-resistivity gold-doped silicon substrate, an exceptionally high-resistivity substrate can be achieved, thereby minimizing field-dependent electrical interaction between the substrate and one or more semiconductor devices thereon. Accordingly, harmonic distortion in the semiconductor devices caused by the substrate will be reduced, thereby increasing the performance of the device.

### RELATED APPLICATIONS

This application claims the benefit of U.S. provisional patent application Ser. No. 62/014,876, filed Jun. 20, 2014, the disclosure of which is incorporated herein by reference in its entirety.

### FIELD OF THE DISCLOSURE

The present disclosure relates to silicon-on-insulator (SOI) semiconductor devices, and specifically to methods for manufacturing SOI semiconductor devices having low harmonic distortion.

### BACKGROUND

Silicon-on-insulator (SOI) semiconductor die structures continue to gain popularity due to the performance enhancements associated therewith.

Generally, devices formed on SOI semiconductor die structures have a reduced parasitic capacitance, higher resistance to latch-up, higher manufacturing yield, and lower leakage currents when compared to devices formed on non-SOI die structures such as bulk complementary metal-oxide-semiconductor (CMOS) structures. FIG. 1 shows a cross-sectional view of a conventional SOI semiconductor die 10. The conventional SOI semiconductor die 10 includes a substrate 12, an insulating layer 14 over the substrate 12, and a device layer 16 over the insulating layer 14. One or more semiconductor devices 18 are located in the device layer 16. For purposes of illustration, the semiconductor devices 18 are shown as a number of field effect transistors (FETs) 20 coupled in series by a number of interconnects 22 between an input 24 and an output 26 to form a stacked FET radio frequency (RF) switch. Each one of the FETs 20 includes a source 28, a source contact 30 over the source 28, a body 32, a gate oxide layer 34 over the body 32 and a gate contact 36 over the gate oxide layer 34, a drain 38, and a drain contact 40 over the drain 38. Further, the FETs 20 are connected in series such that the drain contact 38 of one of the FETs 20 is coupled to the source contact 30 of another one of the FETs 20 via one of the interconnects 22, such that the input 24 is coupled to the source contact 30 of a first one of the FETs 20 and the output 26 is coupled to a drain contact 40 of a last one of the FETs 20.

While the semiconductor devices 18 in the device layer 16 of the conventional SOI semiconductor die 10 may enjoy many of the performance improvements described above, the semiconductor devices 18 may be subject to excessive harmonic distortion when operated at high frequencies. Specifically, the resistivity of the substrate 12 in the conventional SOI semiconductor die 10 must be very high in order to prevent field-dependent electrical interaction (i.e., cross-coupling or cross-talk) of the semiconductor devices 18 and/or the interconnects 22 through the substrate 12, as this cross-talk may result in non-linear behavior and thus harmonic distortion. In the conventional SOI semiconductor die 10 in which the substrate 12 is silicon, this means that most or all impurities must be carefully removed during the crystal growth of the substrate 12. Such a process is generally very expensive and not suitable for high-volume manufacturing. Due to the expense and difficulty in manufacturing a high-resistivity substrate, conventional SOI semiconductor die structures will often include a substrate with a sub-optimal resistivity, resulting in cross-talk, non-linear behavior, and harmonic distortion, especially at high frequencies of operation such as radio frequencies.

Additionally, even if the substrate 12 has a high resistivity, fixed charges in the insulating layer 14 may attract charge carriers in the substrate 12 towards the insulating layer 14, resulting in an accumulation of charge carriers at the interface of the substrate 12 and the insulating layer 14. This accumulation of charge carriers may reduce the effective resistivity of the substrate 12, resulting in cross-talk between the various semiconductor devices 18 that in turn results in non-linear behavior and harmonic distortion. The harmonic distortion generated as a result of the layer of accumulated charge may be especially problematic at high frequencies such as radio frequencies. Due to stringent spectral masking and noise requirements of modern telecommunications standards, this excess harmonic distortion may render the conventional SOI semiconductor die 10 unusable in many RF applications.

In an effort to reduce the accumulation of charge carriers at the interface of the substrate 12 and the insulating layer 14, some designers have turned to the use of a charge trap layer between the substrate 12 and the insulating layer 14. Accordingly, FIG. 2 shows the conventional SOI semiconductor die 10 further including a charge trap layer 42 between the substrate 12 and the insulating layer 14. The charge trap layer 42 is a trap-rich layer that effectively stops or demobilizes charge carriers by reducing their mobility. Accordingly, the accumulation of these charge carriers is significantly reduced, thereby restoring the effective resistivity of the substrate 12 and preventing cross-talk between the semiconductor devices 18. Various designers have used polysilicon and/or amorphous silicon layers for the charge trap layer 42. While generally effective at reducing harmonic distortion in the conventional SOI semiconductor die 10, providing the charge trap layer 42 requires an additional manufacturing step, which may add delay and expense to the manufacture of the conventional SOI semiconductor die 10. Further, the charge trap layer 42 does not alleviate the need for the substrate 12 with a high-resistivity, which may add significant expense to the conventional SOI semiconductor die 10 and further may prevent high volume manufacturing thereof as discussed above.

Accordingly, there is a need for an improved SOI semiconductor device capable of operating at high frequencies with reduced harmonic distortion and methods for manufacturing the same.

### SUMMARY

The present disclosure relates to silicon-on-insulator (SOI) semiconductor devices, and specifically to methods for manufacturing SOI semiconductor devices having low harmonic distortion. In one embodiment, a method for manufacturing a semiconductor die includes providing an SOI wafer including a substrate, an insulating layer over the substrate, and a device layer over the insulating layer. A surface of the SOI semiconductor wafer opposite the substrate is mounted to a temporary carrier mount, and the substrate is removed, leaving an exposed surface of the insulating layer. A high-resistivity gold-doped silicon substrate is then provided on the exposed surface of the insulating layer. By providing the high-resistivity gold-doped silicon substrate, an exceptionally high-resistivity substrate can be achieved, thereby minimizing cross-talk between semiconductor devices and/or interconnects in the device layer and increasing the performance thereof. Further, by first providing the completed SOI semiconductor wafer, removing the substrate, and providing the high-resistivity gold-doped silicon substrate, an SOI semiconductor die having low harmonic distortion can be manufactured without the risk of cross-contamination from gold-doping of the high-resistivity gold-doped silicon substrate.

In one embodiment, the doping concentration of gold in the high-resistivity gold-doped silicon substrate is between about 1×10¹⁵ cm⁻³ and 1×10¹⁷ cm⁻³.

In one embodiment, the SOI semiconductor wafer includes one or more semiconductor devices in the device layer. The one or more semiconductor devices may be complementary metal-oxide-semiconductor (CMOS) semiconductor devices. Further, the semiconductor devices may include a number of field effect transistors (FETs) coupled in series between an input and an output to form a radio frequency (RF) switch.

In one embodiment, the SOI semiconductor wafer includes one or more electrical contacts coupled to the one or more semiconductor devices and extending above the device layer. In this embodiment, mounting a surface of the SOI semiconductor wafer opposite the substrate to the temporary carrier mount includes mounting the one or more electrical contacts to the temporary carrier mount. The electrical contacts may be flip chip conductive bumps.

In one embodiment, the method includes removing the SOI semiconductor die from the temporary carrier mount. The temporary carrier mount may be a thick quartz layer including an ultraviolet (UV) sensitive adhesive configured to become solvable upon exposure to UV radiation. In one embodiment, removing the SOI semiconductor wafer from the temporary carrier mount includes exposing the UV sensitive adhesive to UV radiation and providing a solvent configured to remove the UV sensitive adhesive. The method may further include singulating the SOI semiconductor die into a number of SOI semiconductor die.

In one embodiment, removing the substrate includes mechanically grinding the substrate from the exposed surface of the insulating layer. Providing the high-resistivity gold-doped silicon substrate may include bonding the high-resistivity gold-doped silicon substrate to the exposed surface of the insulating layer via a low-temperature wafer bonding process.

In one embodiment, a semiconductor die includes a high-resistivity gold-doped silicon substrate, an insulating layer over the high-resistivity gold-doped silicon substrate, a device layer over the insulating layer, and one or more semiconductor devices in the device layer. By providing the high-resistivity gold-doped silicon substrate, an exceptionally high-resistivity substrate can be achieved, thereby minimizing cross-talk between semiconductor devices in the device layer and improving the performance thereof.

In one embodiment, the doping concentration of gold in the high-resistivity gold-doped silicon substrate is between about 1×10¹⁵ cm⁻³ and 1×10¹⁷ cm⁻³.

In one embodiment, the semiconductor devices include a number of field effect transistors (FETs) coupled in series between an input and an output to form a radio frequency (RF) switch.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIG. 1 shows a cross-sectional view of a conventional silicon-on-insulator (SOI) semiconductor die.

FIG. 2 shows a cross-sectional view of the conventional SOI semiconductor die shown in FIG. 1 including a charge trap layer.

FIG. 3 shows a cross-sectional view of an SOI semiconductor die according to one embodiment of the present disclosure.

FIG. 4 is a flow diagram illustrating a method for manufacturing the SOI semiconductor die shown in FIG. 3 according to one embodiment of the present disclosure.

FIGS. 5A through 5F are cross-sectional views of an SOI semiconductor wafer illustrating the method of FIG. 4 according to one embodiment of the present disclosure.

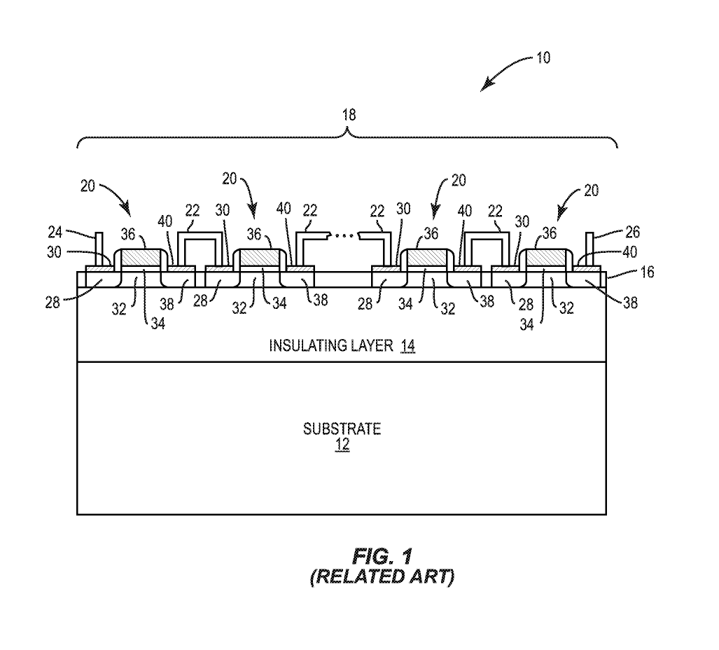

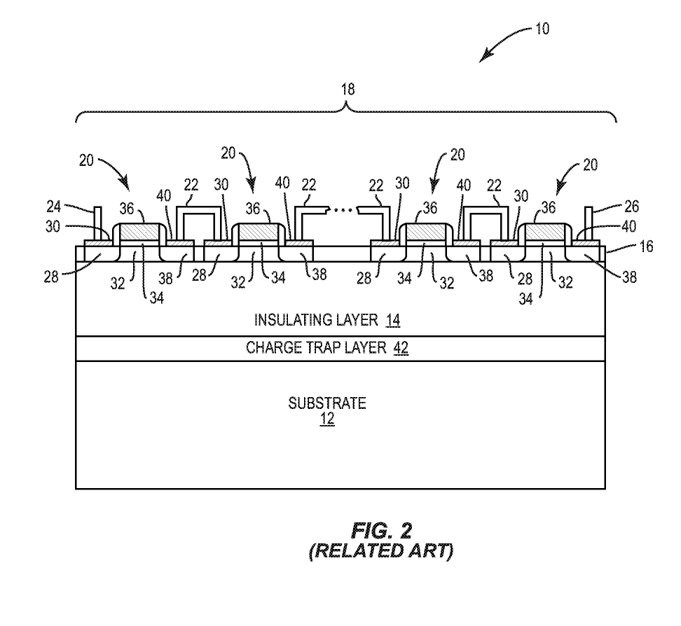

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

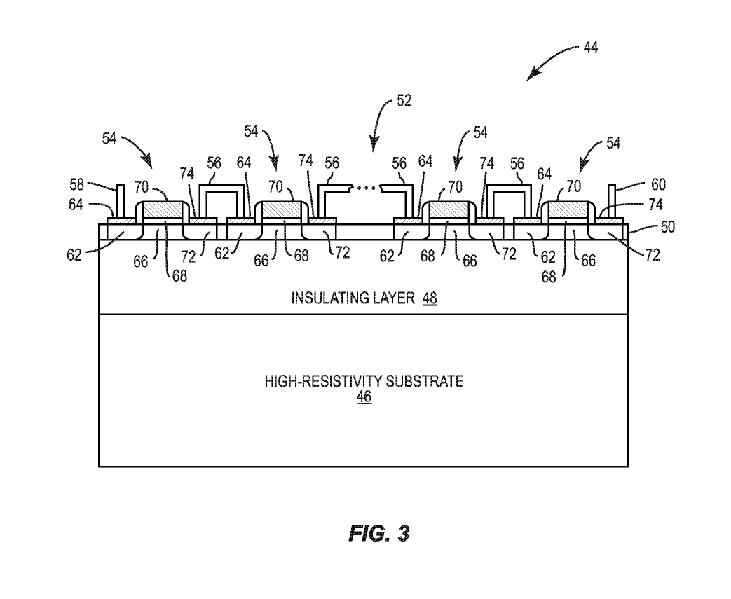

FIG. 3 shows a silicon-on-insulator (SOI) semiconductor die 44 according to one embodiment of the present disclosure. The SOI semiconductor die 44 includes a high-resistivity substrate 46, an insulating layer 48 over the high-resistivity substrate 46, and a device layer 50 over the insulating layer 48. One or more semiconductor devices 52 are located in the device layer 50. For purposes of illustration, the semiconductor devices 52 are shown as a number of field effect transistors (FETs) 54 coupled in series by a number of interconnects 56 between an input 58 and an output 60 to form a stacked FET radio frequency (RF) switch. Each one of the FETs 54 includes a source 62, a source contact 64 over the source 62, a body 66, a gate oxide layer 68 over the body 66 and a gate contact 70 over the gate oxide layer 68, a drain 72, and a drain contact 74 over the drain 72. Further, the FETs 54 are connected in series such that the drain contact 74 of one of the FETs 54 is coupled to the source contact 64 of another one of the FETs 54 via one of the interconnects 56, such that the input 58 is coupled to the source contact 64 of a first one of the FETs 54 and the output 60 is coupled to a drain contact 74 of a last one of the FETs 54. Those of ordinary skill in the art will appreciate that the device layer 50 may include any number of semiconductor devices 52 connected in any desired way without departing from the principles of the present disclosure.

As discussed above, many SOI semiconductor structures suffer from excessive harmonic distortion while operated at high frequencies due to the lack of a high-resistivity substrate and/or an accumulation of charge at the interface of the substrate 46 and the insulating layer 48 that reduces the effective resistivity of the substrate. Accordingly, the high-resistivity substrate 46 is gold-doped silicon. As will be appreciated by those of ordinary skill in the art, doping silicon with gold results in a material with a high propensity for trapping charge carriers, resulting in a material with a low carrier lifetime and a high resistance.

Accordingly, charge carriers are trapped throughout the high-resistivity substrate 46 and do not form a charge layer at the interface of the high-resistivity substrate 46 and the insulating layer 48.

The insulating layer 48 may be any suitable insulating layer, and may comprise, for example, silicon oxide. The device layer 50 may comprise silicon, silicon germanium, silicon carbide, silicon germanium carbide, gallium arsenide, or the like. The high-resistivity substrate 46 may be between 75 μm and 700 μm thick. The insulating layer 48 may be between 200 nm and 1000 nm thick. The device layer 50 may be between 5 μm and 20 μm thick. The semiconductor devices 52 may be formed by any suitable processes, such as ion implantation, selective deposition and/or growth processes, and the like.

As discussed above, the high-resistivity substrate 46 allows the SOI semiconductor die 44 to operate at high frequencies with reduced harmonic distortion. While many materials may provide adequate resistance to be used as the high-resistivity substrate 46, many of these materials may be associated with relatively undesirable thermal properties such as poor thermal conduction. Using gold-doped silicon for the high-resistivity substrate 46 provides the necessary resistance for the substrate while simultaneously providing desirable thermal properties that allow heat to dissipate away from the semiconductor devices 52. In addition to providing desirable performance for the SOI semiconductor die 44, the silicon used with gold doping can achieve this performance without the need for a rigorous or highly controlled growth process as would be required if using silicon alone. While this results in a much cheaper and easier to manufacture high-resistivity substrate 46, gold is often considered a contaminant whose use should be strictly avoided throughout the entirety of many semiconductor fabrication facilities, especially those using complementary metal-oxide-semiconductor (CMOS) fabrication processes. Accordingly, specialty fabrication facilities may be required to fabricate the SOI semiconductor die 44 by conventional means, which may increase the cost thereof significantly and/or make it difficult to procure a supplier.

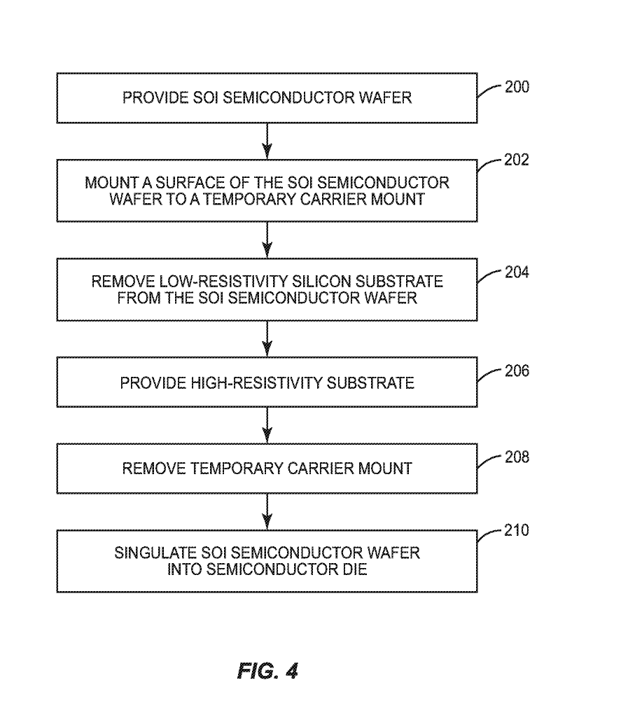

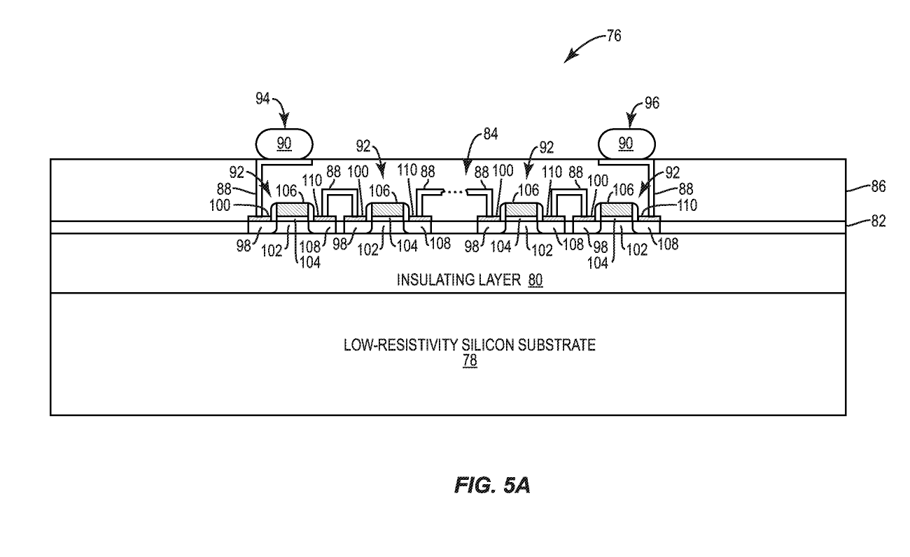

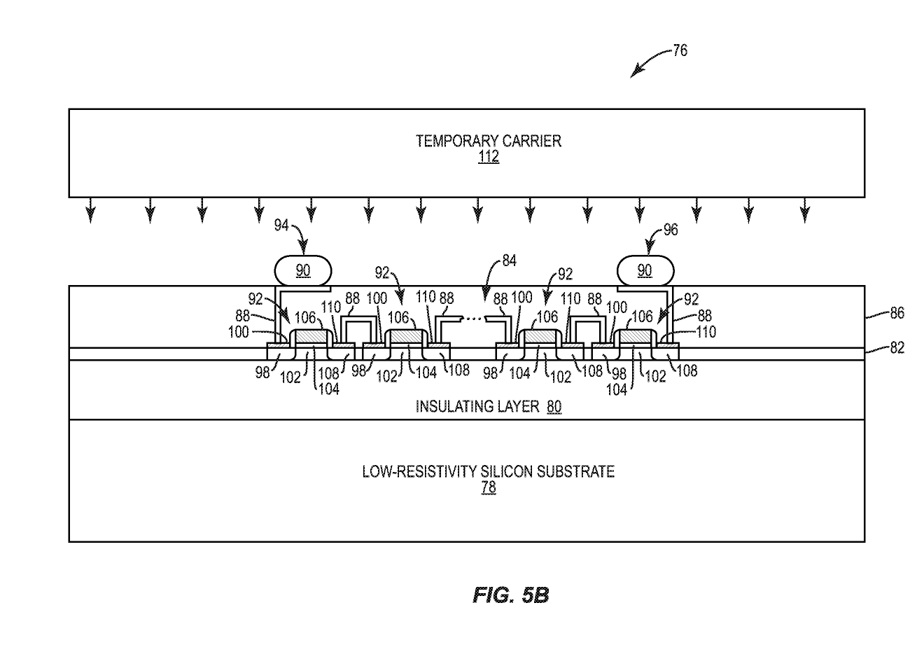

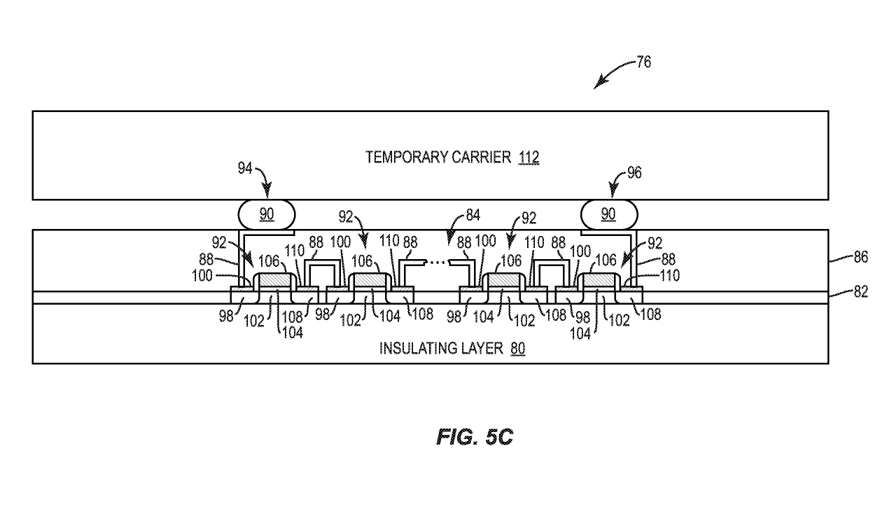

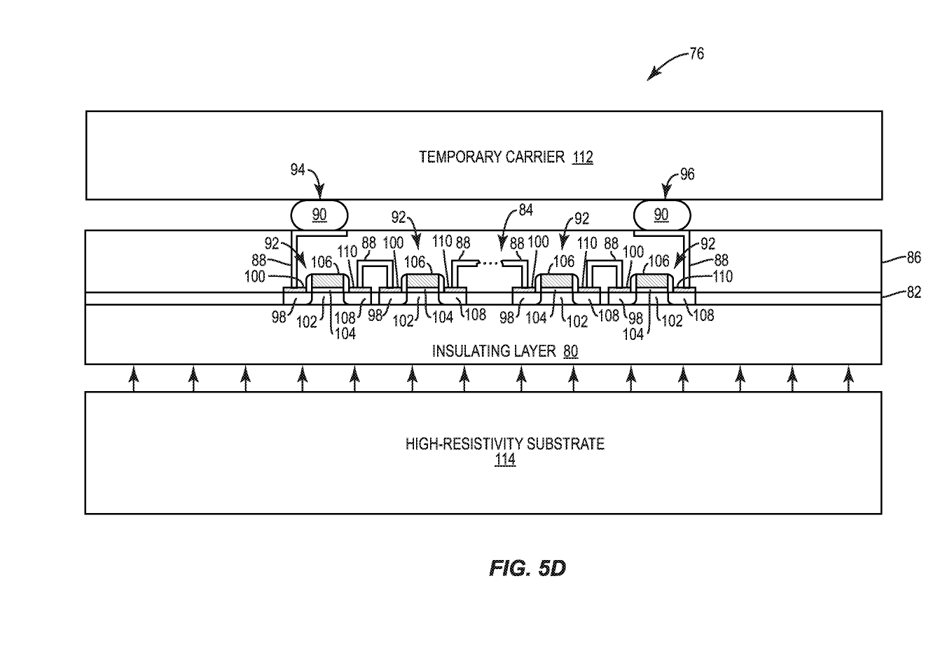

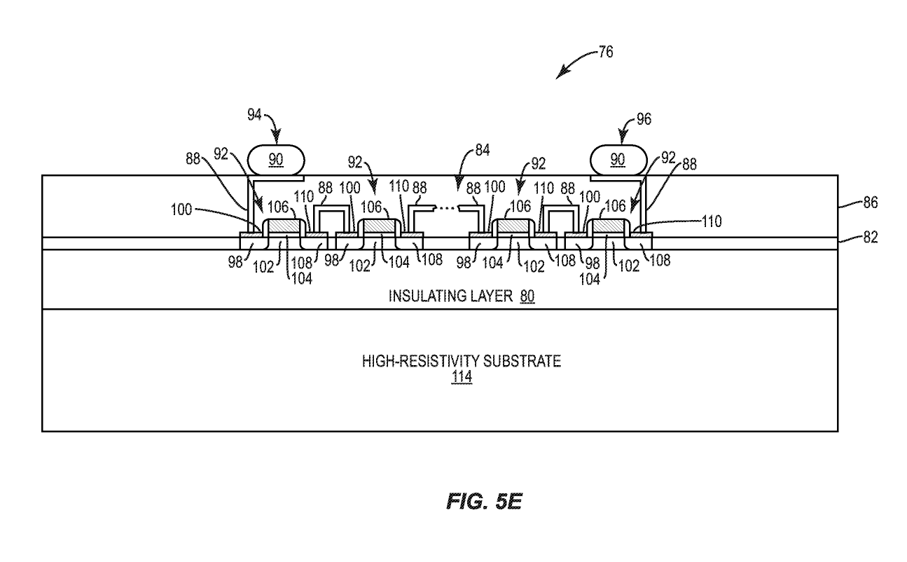

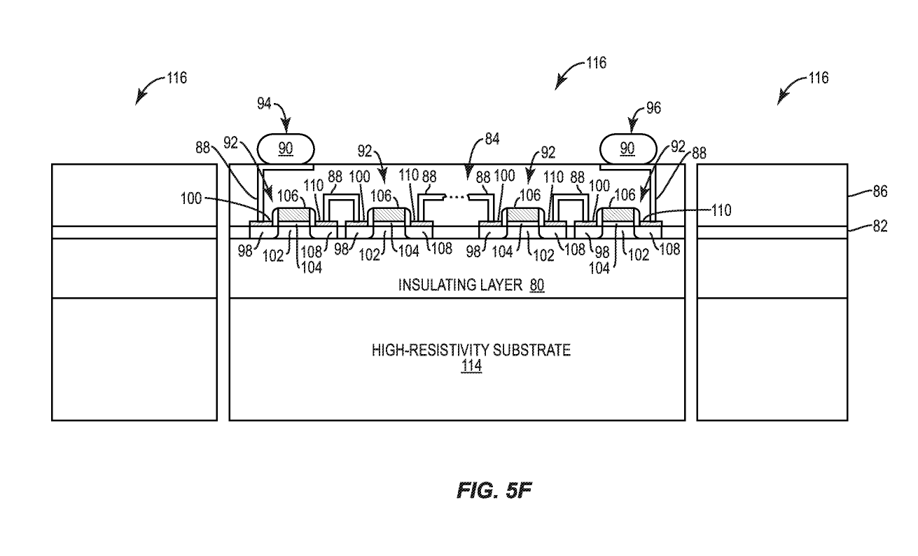

Accordingly, FIGS. 4 and 5A through 5F show a method for manufacturing the SOI semiconductor die 44 shown above according to one embodiment of the present disclosure. First, an SOI semiconductor wafer 76 is provided (step 200 and FIG. 5A). Notably, the SOI semiconductor wafer 76 is a conventional SOI semiconductor structure including a relatively low-resistivity silicon substrate 78. For purposes of the present disclosure, the low-resistivity silicon substrate 78 is a substrate with a resistivity below about 100 Ω/cm³. The remainder of the SOI semiconductor wafer 76 is substantially similar to those described above, and includes an insulating layer 80 over the low-resistivity silicon substrate 78 and a device layer 82 over the insulating layer 80. One or more semiconductor devices 84 are in the device layer 82. Further, the SOI semiconductor wafer 76 includes an inter-layer dielectric (ILD) layer 86, which supports a number of interconnects 88, each of which connect various contacts of the semiconductor devices 84 to one another and/or one or more flip chip conductive bumps 90. While the flip chip conductive bumps 90 are shown on the SOI semiconductor wafer 76, any type of conductive features may be used to couple the SOI semiconductor wafer 76 to external circuitry (not shown).

For purposes of illustration, the semiconductor devices 84 are shown as a number of field effect transistors (FETs) 92 coupled in series by the interconnects 88 between an input 94 and an output 96 to form a stacked FET radio frequency (RF) switch. Each one of the FETs 92 includes a source 98, a source contact 100 over the source 98, a body 102, a gate oxide layer 104 over the body 102 and a gate contact 106 over the gate oxide layer 104, a drain 108, and a drain contact 110 over the drain 108. Further, the FETs 92 are connected in series such that the drain contact 110 of one of the FETs 92 is coupled to the source contact 100 of another one of the FETs 92 via one of the interconnects 88, such that the input 94 is coupled to the source contact 100 of a first one of the FETs 94 and the output 96 is coupled to a drain contact 110 of a last one of the FETs 92. Those of ordinary skill in the art will appreciate that the device layer 82 may include any number of semiconductor devices 84 connected in any desired way without departing from the principles of the present disclosure.

As discussed above, the low-resistivity silicon substrate 78 suffers from significant cross-talk, thereby causing the SOI semiconductor wafer 76 to generate excessive harmonic distortion at high frequencies of operation. Even for conventional high-resistivity substrates made from highly purified silicon, a layer of accumulated charge at the interface of the low-resistivity silicon substrate 78 and the insulating layer 80 may cause a significant reduction in the effective resistivity of the low-resistivity silicon substrate 78. Accordingly, the SOI semiconductor wafer 76 is mounted to a temporary carrier mount 112 (step 202 and FIG. 5B), and the low-resistivity silicon substrate 78 is removed from the SOI semiconductor wafer 76 (step 204 and FIG. 5C). The temporary carrier mount 112 may be any suitable mounting structure configured to accept the SOI semiconductor wafer 76. In one embodiment, the temporary carrier mount 112 is a thick quartz mounting substrate including an ultraviolet (UV) reactive adhesive on a surface thereof. The UV reactive adhesive may be configured to become solvable (i.e., able to be dissolved with a solvent) upon application of UV radiation, thereby allowing for easy removal of the temporary carrier mount 112 in a later step discussed below. The SOI semiconductor wafer 76 is mounted to the temporary carrier mount 112 such that a surface of the SOI semiconductor wafer 76 opposite the low-resistivity silicon substrate 78 is mounted to the temporary carrier mount 112. In one embodiment, the flip chip conductive bumps 90 are mounted to the temporary carrier mount 112. In another embodiment, the SOI semiconductor wafer 76 is mounted to the temporary carrier mount 112 before the flip chip conductive bumps 90 are applied, such that the surface of the ILD layer 86 is mounted to the temporary carrier mount 112. Those of ordinary skill in the art will appreciate that any suitable surface of the SOI semiconductor wafer 76 may be mounted to the temporary carrier mount 112, so long as there is sufficient access to the low-resistivity silicon substrate 78 to allow for the removal thereof. The low-resistivity silicon substrate 78 may be removed by any suitable process. For example, the low-resistivity silicon substrate 78 may be removed by a mechanical grinding process, a chemical etching process, or the like.

A high-resistivity substrate 114 is then provided over the surface of the insulating layer 80 left exposed after removal of the low-resistivity silicon substrate 78 (step 206 and FIG. 5D). That is, the high-resistivity substrate 114 is provided over the surface of the insulating layer 80 opposite the device layer 82. The high-resistivity substrate 114 may be provided by any suitable process. For example, the high-resistivity substrate 114 may be provided via a relatively low-temperature wafer bonding process. In other embodiments, the high-resistivity substrate 114 may be provided via an oxide bonding process, an anodic bonding process, a glass frit bonding process, a eutectic bonding process, an ultrasonic bonding process, a surface activated bonding process, or any other suitable bonding process. As discussed above, the high-resistivity substrate 114 may be gold-doped silicon. Accordingly, during the bonding process it is important to reduce the diffusion of gold into the insulating layer 80 in order to maintain proper insulating characteristics thereof and thus proper functionality of the SOI semiconductor wafer 76. In other words, a bonding process for bonding the high-resistivity substrate 114 to the insulating layer 80 must be carefully chosen in order to maximize bonding between the two layers while simultaneously preventing the diffusion of dopants that may be present in the high-resistivity substrate 114 into the insulating layer 80 or any other layers of the SOI semiconductor wafer 76.

Next, the SOI semiconductor wafer 76 is removed from the temporary carrier mount 112 (step 208 and FIG. 5E). The SOI semiconductor wafer 76 may be removed from the temporary carrier mount 112 by any suitable means.

As discussed briefly above, in one embodiment the SOI semiconductor wafer 76 is mounted to the temporary carrier mount 112 via a UV reactive adhesive that becomes solvable after exposure to UV radiation. Accordingly, removing the SOI semiconductor wafer 76 from the temporary carrier mount 112 may include exposing the UV reactive adhesive holding the SOI semiconductor wafer 76 to the temporary carrier mount 112 to UV radiation, and subsequently applying a solvent thereto. Those of ordinary skill in the art will appreciate that any suitable means to mount the SOI semiconductor wafer 76 to the temporary carrier mount 112 may be used, and thus removing the SOI semiconductor wafer 76 from the temporary carrier mount 112 may involve any number of different steps.

Finally, the SOI semiconductor wafer 76 is singulated to form a number of semiconductor die 116 (step 210 and FIG. 5F). Singulating the SOI semiconductor wafer 76 may involve mechanically cutting between various semiconductor die located on the SOI semiconductor wafer 76, thereby physically separating the semiconductor die from one another. Any number of singulation processes may be used to separate the semiconductor die on the SOI semiconductor wafer 76 including sawing, laser sawing, laser scribing, or diamond scribing.

Those skilled in the art will recognize improvements and modifications to the embodiments of the present disclosure. All such improvements and modifications are considered within the scope of the concepts disclosed herein and the claims that follow.

What is claimed is:

1. A method comprising:
providing a semiconductor-on-insulator (SOI) semiconductor wafer comprising a substrate, an insulating layer over the substrate, and a device layer over the insulating layer;
mounting a surface of the SOI semiconductor wafer opposite the substrate to a temporary carrier mount;
removing the substrate, leaving an exposed surface of the insulating layer; and
providing a high-resistivity gold-doped silicon substrate on the exposed surface of the insulating layer.

2. The method of claim 1 wherein a doping concentration of gold in the high-resistivity gold-doped silicon substrate is between about 1×10¹⁵ cm⁻³ and 1×10¹⁷ cm⁻³.

3. The method of claim 1 wherein the SOI semiconductor wafer further comprises one or more semiconductor devices in the device layer.

4. The method of claim 3 wherein the one or more semiconductor devices are complementary metal-oxide-semiconductor (CMOS) semiconductor devices.

5. The method of claim 4 wherein the one or more semiconductor devices comprise a plurality of field effect transistors (FETs) coupled in series between an input and an output.

6. The method of claim 3 wherein the SOI semiconductor wafer further comprises one or more electrical contacts coupled to the one or more semiconductor devices and extending above the device layer.

7. The method of claim 6 wherein mounting a surface of the SOI semiconductor wafer opposite the substrate to the temporary carrier mount comprises mounting the one or more electrical contacts to the temporary carrier mount.

8. The method of claim 7 wherein the one or more electrical contacts are flip chip conductive bumps.

9. The method of claim 1 further comprising removing the SOI semiconductor wafer from the temporary carrier mount.

10. The method of claim 9 further comprising singulating the SOI semiconductor wafer into a number of SOI semiconductor die.

11. The method of claim 1 wherein the temporary carrier mount is a thick quartz material.

12. The method of claim 11 wherein the SOI semiconductor wafer is mounted to the temporary carrier mount via an ultraviolet (UV) sensitive adhesive configured to become solvable upon exposure to UV radiation.

13. The method of claim 12 further comprising removing the SOI semiconductor wafer from the temporary carrier mount.

14. The method of claim 13 wherein removing the SOI semiconductor wafer from the temporary carrier mount comprises exposing the UV sensitive adhesive to UV radiation and exposing the temporary carrier mount to a solvent configured to remove the UV sensitive adhesive.

15. The method of claim 1 wherein removing the substrate comprises mechanically grinding the substrate from the exposed surface of the insulating layer.

16. The method of claim 1 wherein providing the high-resistivity gold-doped silicon substrate on the exposed surface of the insulating layer comprises bonding the high-resistivity gold-doped silicon substrate to the exposed surface of the insulating layer via a low-temperature wafer bonding process.

17. A semiconductor die comprising:
a high-resistivity gold-doped silicon substrate;
an insulating layer over the high-resistivity gold-doped silicon substrate;
a device layer over the insulating layer; and
one or more semiconductor devices in the device layer.

18. The semiconductor die of claim 17 wherein doping concentration of gold in the high-resistivity gold-doped silicon substrate is between about 1×10¹⁵ cm⁻³ and 1×10¹⁷ cm⁻³.

19. The semiconductor die of claim 17 wherein the one or more semiconductor devices are complementary metal-oxide-semiconductor (CMOS) semiconductor devices.

20. The semiconductor die of claim 19 wherein the one or more semiconductor devices comprise a plurality of field effect transistors (FETs) coupled in series between an input and an output to form a radio frequency (RF) switch.
